(19) United States
(12) Patent Application Publication
(10) Pub. No.: US 2013/0249011 A1
(43) Pub. Date: Sep. 26, 2013

(54) INTEGRATED CIRCUIT (IC) HAVING TSVS AND STRESS COMPENSATING LAYER

(71) Applicants: YOUN SUNG CHOI, ALLEN, TX (US); JEFFREY A. WEST, DALLAS, TX (US)

(72) Inventors: YOUN SUNG CHOI, ALLEN, TX (US); JEFFREY A. WEST, DALLAS, TX (US)

(73) Assignee: TEXAS INSTRUMENTS INCORPORATED, Dallas, TX (US)

(21) Appl. No.: 13/530,744

(22) Filed: Jun. 22, 2012

Related U.S. Application Data
(60) Provisional application No. 61/614,095, filed on Mar. 22, 2012.

(51) Int. Cl. H01L 23/48; H01L 27/092

(52) U.S. Cl. 257/369; 257/741; 257/E23.011; 257/E27.062

(57) ABSTRACT

A through-substrate via (TSV) unit cell includes a substrate having a topside semiconductor surface and a bottomside surface, and a TSV which extends the full thickness of the substrate including an electrically conductive filler material surrounded by a dielectric liner that forms an outer edge for the TSV. A circumscribing region of topside semiconductor surface surrounds the outer edge of the TSV. Dielectric isolation is outside the circumscribing region. A tensile contact etch stop layer (t-CESL) is on the dielectric isolation, and on the circumscribing region.

### CROSS REFERENCE TO RELATED APPLICATIONS

This application claims the benefit of Provisional Application Ser. No. 61/614,095 entitled “MINIMIZING TSV PROXIMITY EFFECT FOR STRAIN-SENSITIVE TRANSISTORS USING TENSILE FILM OVER SUBSTRATE NEAR TSVS”, filed Mar. 22, 2012, which is herein incorporated by reference in its entirety.

### FIELD

Disclosed embodiments generally relate to the fabrication of integrated circuit (IC) devices and, more specifically, to ICs having through-substrate vias.

### BACKGROUND

Vias are routinely used in forming ICs. Vias may be formed that extend from the bottomside surface of an IC die to one of the metal interconnect layers on the active or topside semiconductor surface of the IC die. Such structures are often referred to as “through-silicon vias,” and are referred to more generally herein as through-substrate vias (TSVs).

TSVs are generally framed by a dielectric liner and are then filled with copper or another electrically conductive TSV filler material to provide a low resistance vertical electrical connection between the bottomside of the IC die and the active circuitry on the topside semiconductor surface of the IC die. The active circuitry formed on the topside semiconductor surface comprises circuit elements functionally connected together that generally include transistors, diodes, capacitors, and resistors, as well as signal lines and other conductors that interconnect these various circuit elements to provide a circuit function.

A diffusion barrier metal formed on the dielectric liner frames the TSV and protects against escape of the TSV filler material into the semiconductor in the case of highly mobile metal TSV filler materials, such as copper. Copper, as well as some other TSV filler metals, have a significantly higher coefficient of thermal expansion (CTE) as compared to silicon. For example, copper has a CTE of approximately 17 ppm/° C., whereas silicon has a CTE of approximately 2 to 3 ppm/° C. This CTE mismatch can result in significant thermally induced mechanical stress in the silicon and copper (or other conductive material filling the TSV) during certain fab processing (e.g., 360 to 410° C. sinters) subsequent to the fabrication of the TSV, during assembly (e.g., up to about 260° C. during solder reflow), during test (e.g., −55° C. to 125° C. for certain temperature cycle reliability testing), and even during long-term field operation of the IC (e.g., 80 to 105° C.).

In addition, when the TSVs are spaced relatively close together such that their stress fields interact, these stresses may be further magnified. The stresses that may result from the above-described CTE mismatch can lead to numerous problems, including interfacial delamination, cracking of the semiconductor material (e.g., silicon) or the dielectric above or lateral to the TSV, and/or degraded transistor performance.

A number of solutions have been proposed to reduce problems caused by CTE mismatches for ICs having TSVs. Some solutions rely on TSV geometry or spacing. For example, one solution reduces the diameter of TSVs in order to reduce the stress from each TSV. However, this solution raises the resistance of the TSVs and also raises the aspect ratio of the TSVs, which can add complexity to the fabrication process. Another solution is to position the TSVs far apart from one another to limit the interaction of the stress fields between adjacent TSVs. A further solution is to position the TSVs far from any active circuitry, such as transistors, by establishing “keep-out zones” to ensure stress fields are sufficiently diminished within the area proximate the active circuitry. Spacing solutions reduce packing density and can increase die size and cost.

Other solutions rely on material substitutions. For example, tungsten can be substituted for copper to reduce the CTE mismatch with silicon. However, switching the TSV filler material from copper to tungsten (W) adds significant electrical resistance (W has about 5× the resistance as compared to copper), and can complicate wafer backside processing since W does not generally allow direct electroless plating.

### SUMMARY

Disclosed embodiments recognize the large CTE mismatch between through-substrate via (TSV) filler material such as Cu and substrates such as Si generates a source of mechanical strain on the substrate near the TSVs that interferes with the expected/engineered strain on complementary metal-oxide-semiconductor (CMOS) transistors positioned in the active area proximate to the edge of the TSVs. This mechanical strain has resulted in the need for transistor keep-out zones of about 10 μm or more measured from the outer edge of the TSV to the transistor to maintain desired transistor performance, and/or a reduction in TSV diameter that can cause the aspect ratio (AR) to exceed 7.5 which increases TSV resistance and increases the complexity of the TSV fabrication process.

Disclosed embodiments counter the TSV-induced tensile strain in the active area of the substrate with an overlying tensile contact etch stop layer (t-CESL) that is positioned over the substrate (e.g., silicon), or silicide on the substrate. The t-CESL imparts a compressive stress on the underlying substrate which counters the tensile stress impact of nearby TSVs.

The t-CESL has been found to enable significantly reducing the transistor keep-out zone spacing from the outer edge of TSVs from about 10 μm to 2 to 4 μm, which allows a reduction in the IC die size. Although generally described with respect to MOS transistors, bipolar transistors can also enjoy benefits from a disclosed t-CESL, such as in the case of BiCMOS ICs.

One embodiment is a TSV unit cell comprising a substrate having a topside semiconductor surface and a bottomside surface, and a TSV which extends the full thickness of the substrate comprising an electrically conductive filler material surrounded by a dielectric liner that forms an outer edge for the TSV. A circumscribing region of the topside semiconductor surface surrounds the outer edge of the TSV. Dielectric isolation surrounds the circumscribing region. A t-CESL is on the dielectric isolation, and on the circumscribing region. The dielectric isolation can comprise shallow trench isolation (STI) or deep trench isolation (DTI).

Disclosed embodiments also include integrated circuits (ICs) comprising a plurality of transistors including a first metal-oxide-semiconductor (MOS) transistor having a gate, source and drain, wherein at least the source or drain is positioned proximate the outer edge of the TSV. As used herein, “proximate” refers to a distance of ≦8 μm, such as 2 to 4 p.m. The t-CESL can be used as a stressor for NMOS transistors, such as on the gate, source and drain.

### BRIEF DESCRIPTION OF THE DRAWINGS

Reference will now be made to the accompanying drawings, which are not necessarily drawn to scale, wherein:

FIG. 1 is a schematic illustration of how a disclosed t-CESL minimizes TSV-induced tensile strain near the active area surface using shallow trench isolation (STI), according to an example embodiment.

FIGS. 2A and 2B are top view depictions of a TSV unit cell having a disclosed t-CESL thereon shown in FIG. 2B in an area defined inside the TSV unit cell to minimize the TSV-induced proximity effect to adjacent active areas, according to an example embodiment.

FIG. 3A is a simplified cross sectional depiction of an example IC showing TSV units cells having a disclosed a t-CESL and a CMOS inverter where the NMOS transistor has the t-CESL on its gate, source and drain, according to an example embodiment.

FIG. 3B is simplified cross sectional depiction of an example IC comprising a plurality of transistors including disclosed t-CESL and a plurality of TSVs including a “power TSV” and a “signal TSV,” according to an example embodiment.

FIG. 4 provides NMOS and PMOS current drive (I_{ON}) data as a function of distance from a 10 μm size TSV comprising a copper filler, where the TSV unit cell included a disclosed t-CESL. The I_{ON} shift between 4 μm and 30 μm away from the edge of the TSV can be seen to be less than 1.5% (relative to the I_{ON} value at a distance of 30 μm), for both PMOS and NMOS transistors.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

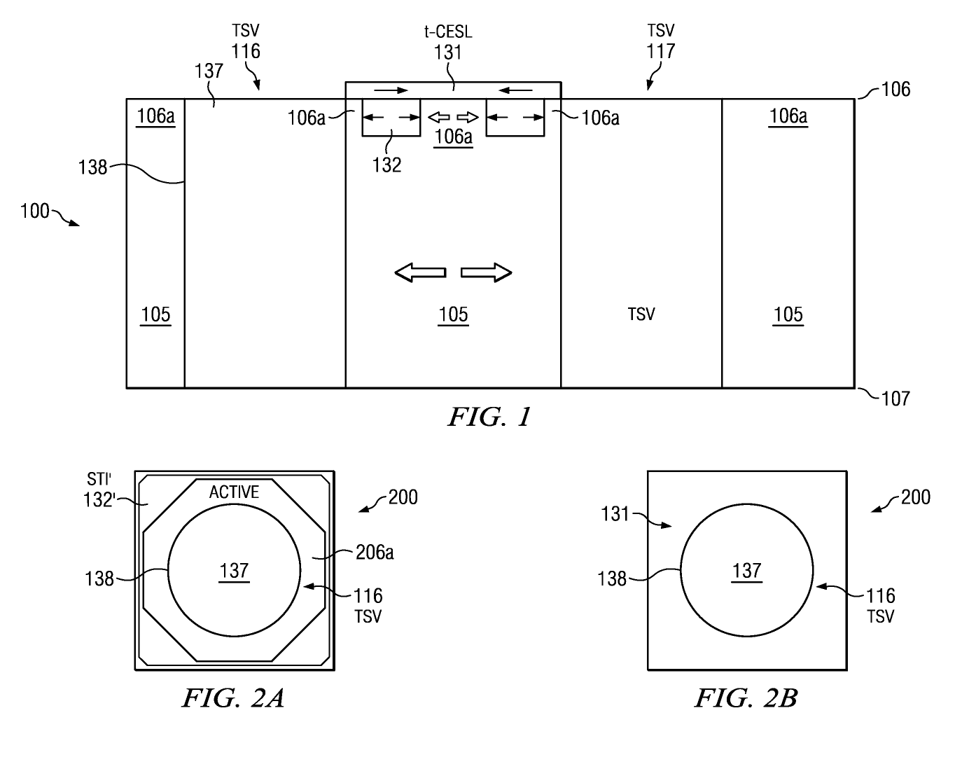

FIG. 1 is a schematic illustration 100 of how disclosed t-CESL minimizes TSV-induced tensile strain near the active area 106a in the topside semiconductor surface 106 having dielectric isolation shown as shallow trench isolation (STI) 132 and a disclosed t-CESL 131, according to an example embodiment. In one embodiment the substrate 105 comprises silicon. Illustration 100 shows a first TSV 116 and a second TSV 117 which both extend through the full thickness of the substrate 105, which in a typical embodiment extends continuously from a TSV terminating metal interconnect level selected from the plurality of metal interconnect levels downward to the bottomside surface 107 of the substrate 105. The TSVs 116 and 117 comprise an electrically conductive filler material 137, such as copper, surrounded by a dielectric liner 138. Although the TSVs 116, 117 are not shown protruding from the bottomside surface 107, the TSVs 116, 117 may include protruding TSV tips which can protrude from 2 μm to 12 μm out from the bottomside surface 107.

The STI 132 are shown providing compressive stress, which along with t-CESL 131, help to compensate for TSV-induced tensile strain in the active area 106a of the topside semiconductor surface 106 of substrate 105. Although STI 132 are shown, other forms of compressive dielectric isolation including Deep Trench Isolation (DTI) or Local Oxidation of Silicon (LOCOS) may be used. The larger size arrows shown in FIG. 1 depict the TSV-induced tensile strain in the substrate 105 away from the stress compensating effect provided by t-CESL 131 and STI 132. The smaller arrows depict the mitigated TSV-induced tensile strain near the topside semiconductor surface 106 are due to the compensating effects of the disclosed t-CESL 131 and STI 132. t-CESL 131 is shown directly on the topside semiconductor surface 106 over STI 132 and over the active area 106a. t-CESL 131 can comprise silicon nitride (SiN) or silicon oxy-nitride (SiON). In other embodiments, other dielectric layer materials may be used, or even some undoped or lightly doped semiconductor materials. t-CESL 131 can be deposited using chemical vapor deposition (CVD) techniques optionally after the conventional salicide formation, and as known in the art can produce compressive or tensile stress depending on the deposition conditions.

In one embodiment, since stress has different impact on electrons and holes, both compressive and tensile stress may be used for enhancing the performance of CMOS transistors in what is referred to as dual stress liner technology (DSL). In DSL, a t-CESL is deposited over the entire wafer, followed by patterning and etching the t-CESL off the area of the PMOS transistors. Afterwards, a compressive CESL is deposited and is etched off the area of the NMOS transistors. Thus the performance of the NMOS and PMOS devices can be improved simultaneously, including improvements in both the linear as well as the saturation drain currents.

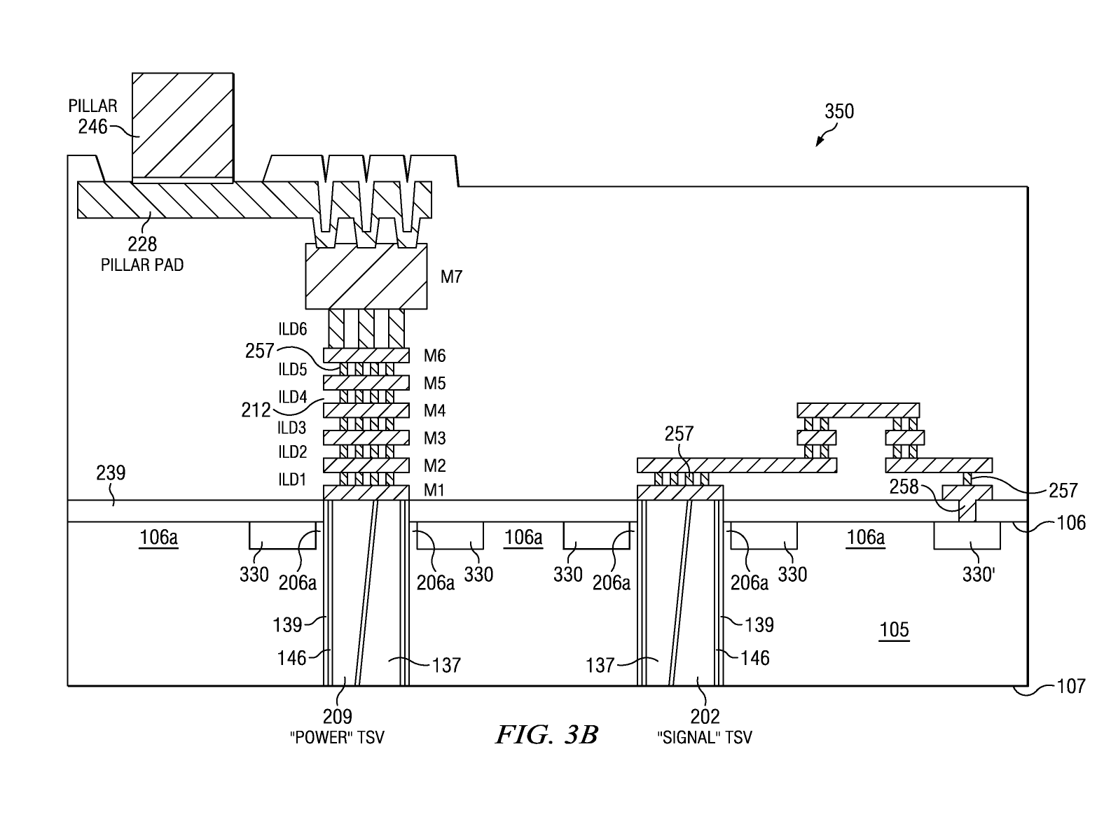

Although not shown in FIG. 1, the t-CESL 131 can also be used for stress enhancements for NMOS transistors by placement on the gate, source and drain, such as directly on a silicide layer that is on the gate, source and drain. t-CESL 131 is generally deposited as a continuous layer, and may have a thickness in the range of 10 nm to 100 nm, such as 20 nm to 80 nm thick. After depositing t-CESL 131, although not shown in FIG. 1, conventional photolithography techniques can be used to pattern the t-CESL 131 to provide apertures therethrough, such as between the STI's 132 shown where transistors can be placed, and optionally to also form t-CESL segments. In typical processing, after patterning the t-CESL 131 and optional compressive-CESL (see c-CESL 332 in FIG. 3A for PMOS described below), a pre-metal dielectric (PMD) layer is deposited over the t-CESL 131 or CESLs. The PMD layer in one embodiment may be silicon oxide (SiO₂), deposited by a conventional oxide deposition process to a thickness in the range of 150 nm-1000 nm.

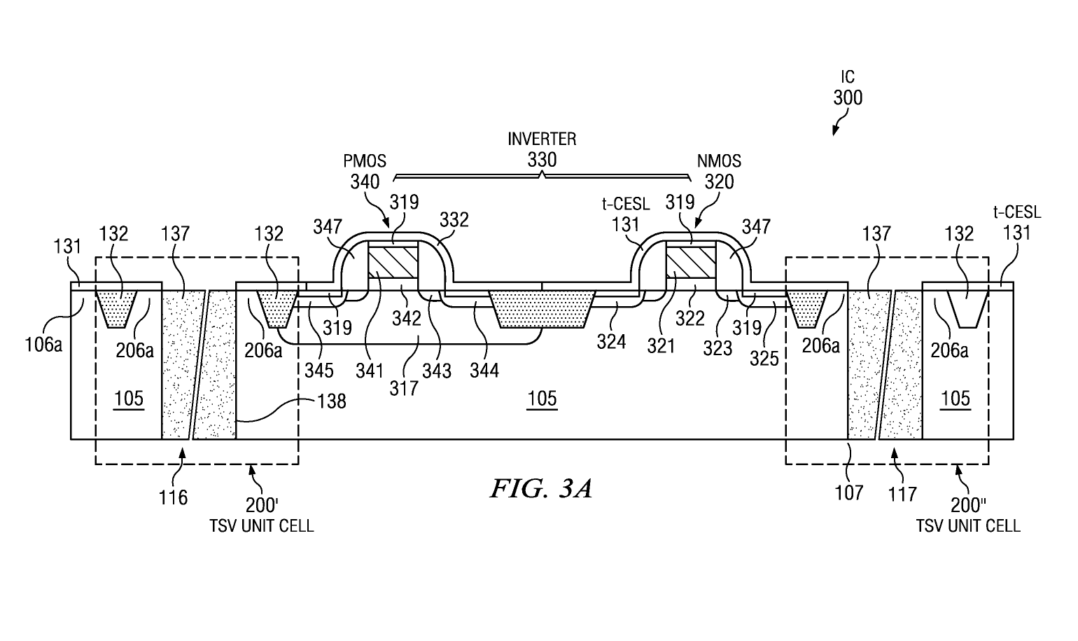

FIGS. 2A and 2B are top view depictions of an example TSV unit cell 200, according to an example embodiment. FIG. 2A has the t-CESL 131 removed to show features thereunder, while FIG. 2B shows the t-CESL 131 thereon. In FIG. 2A, the view is that of a transverse “slice” through the TSV unit cell 200 just below the topside semiconductor surface 106, while the view in FIG. 2B is that of a transverse slice of the TSV unit cell 200 through the t-CESL layer 131. The t-CESL 131 covers an area inside the TSV unit cell 200 to minimize the TSV-induced proximity effect of tensile stress surrounding the TSV unit cell 200.

The dielectric liner 138 forms an outer edge (or TSV boundary) for the TSV 116. As shown in FIG. 2A, a circumscribing region of the topside semiconductor surface shown as 206a surrounds the outer edge of the TSV, and dielectric isolation shown as STI′ 132′ is outside the circumscribing region 206a. As shown in FIG. 2B, the t-CESL 131 is on the STI′ 132′ and the circumscribing region 206a, and extends to the dielectric liner 138.

Although the TSV unit cell 200 is shown square shaped, the TSV 116 shown having a circular cross section and the active area 106a being octagon shaped, other shapes may be used. As described above, the STI stress to the active area 106a of the topside semiconductor surface 106 is compressive and thus provides stress buffering.

The STI′ 132′ is at least mostly (by area) STI and is thus used to also help counteract TSV-induced tensile stress. Polysilicon may be optionally patterned over the STI′ 132′ which helps local gate length sizing uniformity by providing a desired local poly gate pattern density.

FIG. 3A is a simplified cross sectional depiction of an IC 300 showing a CMOS inverter 330 in an active area 106a of the topside semiconductor surface 106 between TSV unit cells 200′ and 200″ that includes a disclosed t-CESL 131 on the TSV unit cells, according to an example embodiment. The CMOS inverter 330 comprises an NMOS transistor 320 and PMOS transistor 340 (coupling between NMOS transistor 320 and PMOS transistor 340 not shown). Reference 317 represents an nwell, while substrate 105 can be a p-substrate or a p-epi layer on a p+ substrate. PMOS transistor 340 comprises gate electrode 341, gate dielectric 342, sidewall spacer 347, lightly doped drains 343, source 344, and drain 345, with a silicide layer 319 on the source 344, drain 345, and gate electrode 341 for the case the gate electrode 341 comprises polysilicon. NMOS transistor 320 comprises gate electrode 321, gate dielectric 322, sidewall spacer 347, lightly doped drains 323, source 324 and drain 325, with a silicide layer 319 on the source 324, drain 325 and gate electrode 321 for the case the gate electrode 321 comprises polysilicon.

The vertical cut-lines through the TSVs 116 and 117 shown in FIG. 3A and FIG. 3B described below are intended to clarify the TSVs are >>in size as compared to the transistors, such as the NMOS transistor 320 and PMOS transistor 340 shown in FIG. 3A. The t-CESL 131 is shown extending to the dielectric liner 138 of the TSVs 116, 117. t-CESL 131 is also shown on the silicide layer 319 on the gate electrode 321, source 324 and drain 325 of NMOS transistor 320. However, in some embodiments NMOS transistor 320 will have a stress liner separate (different material and or thickness) from t-CESL 131. There is a c-CESL332 shown in FIG. 3A on the silicide 319 which is on the gate electrode 341, source 344 and drain 345 of the PMOS transistor 340. Although not shown, openings in the c-CESL 332 and t-CESL 131 layers will be formed (e.g., at contact etch) to allow contacts to be made to underlying layers. Although the TSVs 116, 117 are shown planar with respect to t-CESL 131, c-CESL 332 and STI 132, the TSVs 116, 117 generally extend well above the level of the t-CESL 131 and c-CESL 332. For example, in FIG. 3B the TSVs are shown extending to the first metal interconnect.

FIG. 3B is a simplified cross sectional depiction of an example IC 350 comprising a plurality of TSVs including a first TSV shown as a “power TSV” 209 and a second TSV shown as a “signal TSV” 202, with CMOS transistors proximate thereto shown as the CMOS inverter 330 in FIG. 3A which includes a disclosed t-CESL 131 thereon, according to an example embodiment.

IC 350 comprises a substrate 105 having a topside semiconductor surface 106, such as a silicon or silicon germanium top surface, and a bottomside surface 107. The topside semiconductor surface 106 is shown as 106a, and as 206a in the circumscribing regions that surround the outer edge of the TSVs 116, 117. IC 350 includes a plurality of metal interconnect levels including a first to seventh metal interconnect level shown as M1-M7, for example, PMD 239 between the topside semiconductor surface 106 and M1, and ILD layers comprising ILD1, ILD2, ILD3, ILD4, ILD5 and ILD6 shown comprising an ILD material between respective ones of the plurality of metal interconnect levels M1 to M7. ILD material 212 can comprise a low-k or an ultra low-k dielectric layer, and be different (or the same) material for each of the ILD1, ILD2, ILD3, ILD4, ILD 5 and ILD6 layers. Vias are shown as 257, with apertures 258 through the PMD 239.

CMOS inverters 330 are formed on the topside semiconductor surface 106 in the active areas 106a. One of the nodes of one of the CMOS inverters 330′ in FIG. 3B is shown coupled to the signal TSV 202 by one of the many possible connection options comprising M1, M2, M3 and M4 and associated vias as shown. The power TSV 209 is seen providing a feed-through the substrate 105 for connection on the top of the IC 350, such as to the pillar pad 228. Power TSV 209 generally provides a power connection, such as VDD, VSS or Ground to a device above IC 350, with only the copper pillar 246 shown.

As described above, TSVs 202 and 209 comprise electrically conductive filler material (e.g., copper or other metal) 137 that can be seen to extend from M1 which functions as the TSV terminating metal interconnect level for TSVs 202 and 209 on IC 350 downward to the bottomside surface 107. The electrically conductive filler material 137 is shown surrounded by diffusion barrier metal (e.g., Ta, TaN, Ti, TiN, Mn, or Ru, or combinations thereof) 146 then an outer dielectric liner 138. Seed metal generally present under electrically conductive filler material 137 when electrically conductive filler material 137 comprises electroplated rapid diffusing minority carrier lifetime harming metals such as copper is not shown.

The outer edge of the TSVs 202 and 209 is set by the position of the dielectric liner 138. Due to the presence of a disclosed t-CESL 131, transistors in CMOS inverter 330 can be positioned proximate to the TSVs 202 and 209. For example, NMOS transistor 320 may be positioned between 2 μm and 4 μm from the position of the dielectric liner 138 that defines outer edge of the TSVs 202 and 209.

Although IC 350 shows both power TSV 209 and signal TSV 202 terminating at M1 that defines their TSV terminating metal interconnect level, in other embodiments the TSV terminating metal interconnect level can terminate at metal levels above M1, including the top level metal interconnect (M7 shown in FIG. 3B). The process to form such TSVs would still be a via-middle process since the TSV is etched and filled with an electrically conductive filler before the formation of at least one metal interconnect level.

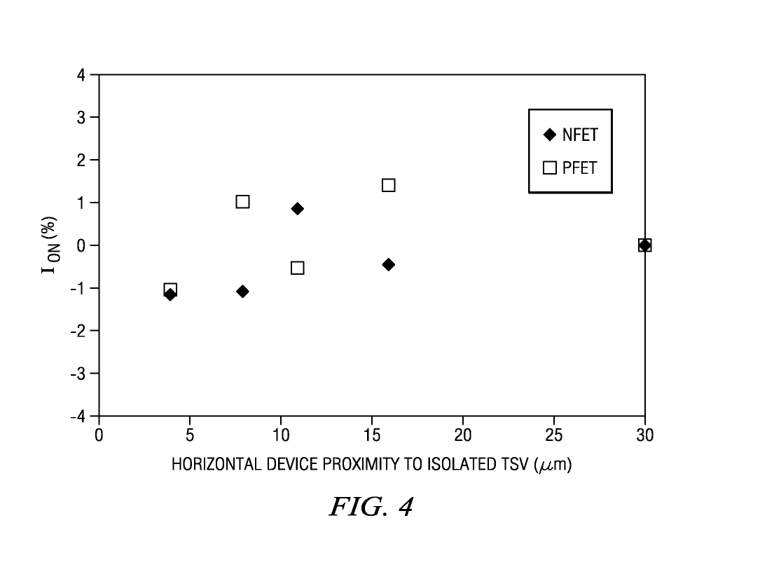

FIG. 4 provides NMOS and PMOS current drive (I_{ON}) data as a function of distance from a 10 μm size TSV comprising a copper filler, where the TSV unit cell included a disclosed t-CESL. The I_{ON} shift between 4 μm and 30 μm away from the edge of the TSV can be seen to be less than about 1.5% (relative to the I_{ON} value at a distance of 30 μm), evidencing essentially no difference in Ion for both PMOS and NMOS transistors.

Advantages of disclosed embodiments include a significant reduction in the size of the keep-out zones from edges of the TSVs to provide desired transistor performance, such as from about 10 μm which is conventionally used to 2 to 4 μm, leading to a smaller die size, and better design compatibility. Disclosed embodiments also enable compatibility with larger diameter TSVs (e.g., 6-10 μm), and hence an aspect ratio <7.5, and avoiding need for more complex/expensive barrier/seed deposition equipment or thin die handling during assembly.

Disclosed embodiments can be integrated into a variety of assembly flows to form a variety of different semiconductor IC devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A through-substrate via (TSV) unit cell, comprising:
a substrate having a topside semiconductor surface and a bottomside surface;
a TSV which extends a full thickness of said substrate comprising an electrically conductive filler material surrounded by a dielectric liner that forms an outer edge for said TSV,
a circumscribing region of said topside semiconductor surface surrounding said outer edge of said TSV;
dielectric isolation outside said circumscribing region, and
a tensile contact etch stop layer (t-CESL) on said dielectric isolation, and on said circumscribing region.

2. The TSV unit cell of claim 1, wherein said t-CESL extends to said dielectric liner.

3. The TSV unit cell of claim 1, wherein said dielectric isolation comprises trench isolation.

4. The TSV unit cell of claim 1, wherein said filler material comprises copper and said topside semiconductor surface comprises silicon.

5. The TSV unit cell of claim 1, wherein said t-CESL comprises silicon nitride or silicon oxynitride.

6. The TSV unit cell of claim 1, wherein said t-CESL is 20 nm to 80 nm thick.

7. An integrated circuit (IC), comprising:
a substrate having a topside semiconductor surface having active circuitry therein including a plurality of transistors functionally connected by a plurality of metal interconnect levels including a first metal interconnect level and a top metal interconnect level having inter-level dielectric (ILD) layers between respective ones of said plurality of metal interconnect levels, and a bottomside surface;
a plurality of through-substrate vias (TSVs) including at least a first TSV which extends from a TSV terminating metal interconnect level selected from said plurality of metal interconnect levels downward to said bottomside surface, said plurality of TSVs comprising an electrically conductive filler material surrounded by a dielectric liner that forms an outer edge for said plurality of TSVs,
said first TSV within a TSV unit cell including:
a circumscribing region of said topside semiconductor surface surrounding said outer edge;
dielectric isolation outside said circumscribing region, and
a tensile contact etch stop layer (t-CESL) on said dielectric isolation and on said circumscribing region, and
wherein a first metal-oxide-semiconductor (MOS) transistor from said plurality of transistors includes a gate, a source and a drain, wherein at least said source or said drain is positioned proximate said outer edge said first TSV.

8. The IC of claim 7, wherein said t-CESL extends to said dielectric liner.

9. The IC of claim 7, wherein said filler material comprises copper and said topside semiconductor surface comprises silicon.

10. The IC of claim 7, wherein said dielectric isolation comprises shallow trench isolation (STI).

11. The IC of claim 7, wherein said t-CESL comprises silicon nitride or silicon oxynitride.

12. The IC of claim 7, wherein said t-CESL is 20 nm to 80 nm thick.

13. The IC of claim 7, wherein said first MOS transistor comprises an NMOS transistor, and said t-CESL is on said gate, said source and said drain.

14. The IC of claim 13, wherein said plurality of transistors include a PMOS transistor including a gate, a source and a drain, further comprising a compressive CESL on said gate, said source and said drain of said PMOS transistor.

15. A through-substrate via (TSV) unit cell, comprising:
a substrate having a topside silicon surface and a bottomside surface;
a TSV which extends a full thickness of said substrate comprising an copper surrounded by a dielectric liner that forms an outer edge for said TSV,
a circumscribing region of said topside silicon surface surrounding said outer edge of said TSV;
trench isolation outside said circumscribing region, and
a tensile contact etch stop layer (t-CESL) on said trench isolation, on said circumscribing region, and extending to said dielectric liner.

16. The TSV unit cell of claim 15, wherein said t-CESL comprises silicon nitride or silicon oxynitride.

17. The TSV unit cell of claim 16, wherein said t-CESL is 20 nm to 80 nm thick.
